(19) United States
(12) Patent Application Publication
(10) Pub. No.: US 2007/0003839 A1
(43) Pub. Date: Jan. 4, 2007

(54) $M(c)method for producing inclined flank patterns by photolithography

(76) Inventors: Marc Rabarot, ST. EGREVE (FR); Mathieu Kipp, Duttlenheim (DE); Christophe Kopp, Fomtamil-Cormillom (FR)

Correspondence Address: THELEN REID & PRIEST, LLP, P. O. BOX 640640, SAN JOSE, CA, 95164-0640, US

(21) Appl. No.: 10/567,889

(22) PCT Filed: Aug. 5, 2004
(86) PCT No.: PCT/FR04/50377

§ 371 Date: Feb. 7, 2006

(30) Foreign Application Priority Data
Aug. 7, 2003 (FR) 0350410

(51) Int. Cl. G03F 1/00

(52) U.S. Cl. 430/5; 430/311

(57) ABSTRACT

The invention concerns a photolithography fabrication method enabling production of patterns in a photosensitive resin layer (601) placed on a substrate (600). The patterns (607) comprise flanks (608) inclined relative to a normal (\vec{n}) relative to the principal plane of the substrate and which have an angle of inclination (θ) far greater to that of the patterns obtained according to the prior art. The invention also concerns a device allowing said method to be executed.

### DESCRIPTION OF TECHNICAL FIELD

The present invention concerns a photolithography method under controlled incidence for micro-components or micro-systems fabrication and a device for implementing said method.

Photolithography is utilised in the fabrication of integrated circuits, and is also the basic technique used for fabricating micro-structures such as MEMS (Micro Electro Mechanical Systems). It consists of producing predefined patterns on a suitable substrate (for example a silicon wafer) so as to locally modify the properties of this substrate (i.e. implementing transistors), or depositing metal at certain points on the substrate to create micro-machines, for example.

### PRIOR ART

Conventionally, a photolithography method is carried out under normal incidence (that is, a layer of resin to be photo-structured is usually perpendicular to the main direction of a light beam by which it is insulated). During a first step, a photosensitive resin layer 101 (for example a hundred micrometers of polyimide) is deposited on a substrate 100 (for example made of silicon) (FIG. 1A). This photosensitive resin layer 101 is then exposed to create patterns on it, by means of a light beam 102 (generally with a wavelength in the ultra-violet range) orthogonal to the principal plane of the layer of resin 101 via a mask 103 comprising opaque parts 104 (for example made of metal) to the light beam 102 and transparent parts 105 (for example silica) to the light beam 102, with the transparent parts 105 able to be holes. The transparent parts 105 are placed according to the patterns to be created. The image of the mask 103 is then projected onto the photosensitive resin layer 101.

At this moment certain parts of the layer of resin 101 are exposed to ultra-violet rays, while others remain intact. The layer of resin 101 therefore comprises insulated zones 106 and non-insulated zones 107 corresponding to the parts of the layer of resin 101 protected by the mask 103 (FIG. 1B).

Finally, the mask 103 is removed, then the layer of resin 101 is developed with chemical products, such as a strong base, which remove the insulated zones 106 of the layer of resin 101 and leave the non-insulated zones 107 in the event where the resin of the layer of resin 101 is a resin of “positive” type (FIG. 1C).

These days, with the advent of micro-techniques, the aim is to obtain micro-structures having more and more complex forms. For this, patterns of resin with inclined flanks are at times to be produced in a photosensitive resin layer during photolithography methods. An example of a method for making patterned resin with inclined flanks consists first of all of depositing a photosensitive resin layer 101 onto a substrate 100 such as illustrated in FIG. 1A. The photosensitive resin layer 101 has a refraction index of N₂. A mask 103 is joined to this layer of resin 101. The mask 103 has opaque parts 104, for example made of chrome, and transparent parts 105, for example made of silica having a refraction index N₁. Next, the substrate 100 covered with the photosensitive resin layer 101 and the mask 103 form an ensemble which is inclined under an ultra-violet light beam 102 of main direction \vec{d}₁. The light beam 102 traverses a layer of air of refraction index N₀ approximately equal to 1 and creates an angle of incidence Î₁ on the mask 103 relative to a normal \vec{n}to the principal plane of the substrate 100, prior to penetrating through the transparent parts 105 of the mask 103. The light beam 102 is then refracted when it passes through the transparent parts 105 of the mask 103. The main direction \vec{d}₁ of the beam 102 is then deflected and creates an incident angle \hat{R}₁ on the layer of resin 101 with a normal n to the principal plane of the substrate 100 at the moment when the beam makes ready to pass through the photosensitive resin layer 101.

The incident angle \hat{R}₁ on the layer of resin 101 is less than the angle of incidence Î₁ on the mask 103, since the beam passes from air to a more refractive medium (N₁>N₀). The light beam 102 then penetrates the photosensitive resin layer 101 of refraction index N₂. The light beam 102 is thus again refracted. In the photosensitive resin layer 101 with the normal \hat{n} the main direction \vec{d}₁ of the beam 102 creates a resulting insulation angle \hat{R}₂ function of incident angle \hat{R}₁, N₂ and N₁ (FIG. 2A). The photosensitive resin layer 101 is therefore insulated by an inclined light beam 102 which creates a resulting insulation angle R₂ with the normal \vec{n} to the principal plane of the substrate 100.

Next, the mask 103 is removed from the photosensitive resin layer 101. The photosensitive resin layer 101 is then developed, for example by means of a strong base. After development, patterns of resin 200 with inclined flanks 201 are obtained (FIG. 2B). The inclined flanks 201 of the patterns 200 form an angle θ with a normal \vec{n} to the principal plane of the substrate 100, approximately equal to the resulting insulation angle \hat{R}₂.

With this production method of patterns of resin 200 with inclined flanks 201, the angle θ of the flanks 201 of the patterns 200 is severely limited. In effect, during the insulating step, the light beam 102 first of all inevitably passes through a layer of air of index N₀, then a mask of index N₁ approximately equal to 1.45 for example for a mask made of silica, then a photosensitive resin layer 101 of refraction index approximately equal to 1.6 (1.67 for a layer of resin 101 of SU-8 type). The important refraction index difference between the layer of air and the mask 103 and the refraction index difference between the mask 103 and the photosensitive resin layer 101 cause an important spread between the angle of incidence Î₁ on the mask 103 and the resulting insulation angle \hat{R}₂. Even when the photosensitive resin layer 101 with an angle of incidence is insulated on the raised mask 103, the resulting insulation angle \hat{R}₂ remains slight. In addition, from a certain value of Î₁, more problems of reflection of the beam 102 on the mask 103 are encountered.

After development of the photosensitive resin layer 101, the angle θ of the flanks 201 of patterns 200 (approximately equal to \hat{R}₂), created by the inclined flanks 201 of the patterns of resin 200 with the normal \hat{n}, is therefore also limited.

The limitation of the angle θ of the patterns of resin 200 is very penalising. It prevents the fabrication of numerous micro-structures. The production of micro-prisms at angles of 45° for example is impossible using such a method.

Further to the limitation of the angle θ of the patterns of resin 200, other problems emerge with the method illustrated in FIG. 2A. First of all, the Fresnel reflections between the mask 103 and the photosensitive resin layer 101. The Fresnel reflections are due to a fine layer of air located inevitably between the mask 103 and the photosensitive resin layer 101. They can cause in particular poor definition of the patterns of resin 200 after the development step of the photosensitive resin layer.

A solution seeking to decrease the Fresnel reflections is described in the document^{[1]} cited at the end of the present description.

During the insulating step illustrated by FIG. 3A, first of all a substrate 100 covered by a photosensitive resin layer 101 is inclined by an angle α, under an ultra-violet light beam 102 of main direction \vec{d}₁ by means of an inclinable plate 300 on which the substrate 100 rests. The photosensitive resin layer 101 is insulated through two masks 301, 302 integrated directly in the photosensitive resin layer 101. The photosensitive resin layer is composed of a base sub-layer 303a of refraction index N₂ which rests on the substrate 100, and an intermediate sub-layer 303b situated above the base sub-layer 303a and refraction index N₁ equal to N₂. The masks 301, 302 are each composed of a metallic layer of titanium or aluminium, separated from one another by the photosensitive intermediate resin sublayer 303b. The mask 301 comprises openings 304. The mask 302 comprises identical openings 305 though offset laterally slightly relative to the openings 304. The main direction \vec{d}₁ of the beam 102 realise an angle of incidence Î₁ on the mask 301 with a normal \vec{n} to the principal plane of the substrate 100 equal to the angle of inclination α, prior to penetrating the photosensitive resin layer 101. When the beam 102 passes through the photosensitive resin layer 101, it is refracted and its main direction \vec{d}₁ creates a resulting insulation angle \vec{R}₂ with the normal \vec{n} to the principal plane of the substrate 100. The photosensitive resin layer 101 is therefore exposed according to a resulting insulation angle \vec{R}₂.

In this example, since the masks 301, 302 are integrated into the photosensitive resin layer 101, the parasite reflections, for example Fresnel-type reflections, are cancelled out since there is no longer a layer of air between mask and resin.

The fact of integrating the masks 302, 303 directly into the photosensitive resin layer 101 therefore provides patterns of superior resolution than with the method example illustrated by FIG. 2A.

The fabrication method for patterns with inclined flanks illustrated by FIG. 3A has even more disadvantages.

First of all, the way the masks 302, 303 are implemented, implies that this method is valuable only for making simple patterns and of a relatively large size (approximately ten micrometers), and on the other hand supplementary steps of photolithography are required to produce the masks 302, 303 integrated into the layer of resin 101 relative to that illustrated in FIG. 2A.

In addition, the disadvantage of the production technique of patterns with inclined flanks by photolithography illustrated by FIG. 3A is still that the angle of inclination θ of the inclined flanks of the patterns of resin remains limited.

Another problem arises during the insulating steps the two methods illustrated earlier by FIGS. 2A and 3A. It is linked to the reflections of the light beam 102 on the substrate 100. In fact, after having passed through the photosensitive resin layer 101, part of the light beam 102 can be reflected onto the substrate 100 and thus form parasite insulation zones 307 outside of desired insulation zones 308 (FIG. 3B). The parasite insulation zones 307 can thus lead to the formation of parasite patterns of resin 333 adding to the desired patterns of resin 200 (FIG. 3C).

The document^{[2]} cited at the end of the present description proposes a method for reducing the problems of reflection on the substrate 100. Before the step of depositing of the photosensitive resin layer 101, the substrate 100 is subjected to a pressurised sand jet of 300 to 500 kPa with grains of SiC. This sand jet serves to roughen the surface 400 of the substrate 100. Therefore, during the insulation phase of the photosensitive resin layer 101, the reflections of the light beam 102 on the substrate 100 become irregular, thus causing a reduction in the parasite insulation zones (FIG. 4). Nevertheless the disadvantage of this method is that it does not fully eliminate the parasite reflections, since it diminishes the exposure time of the layer of resin in the parasite insulation zones by orienting the light beams reflected in very diverse directions.

The document^{[3]} cited at the end of the present description proposes another method utilising a method which in particular helps reduce the problems of reflection on the substrate. This method consists of coupling several polariser filters to a source of light beams to insulate a photosensitive resin layer resting on a substrate, by means of a light beam, the beam being inclined relative to the substrate. The use of a circular polariser filter coupled to a rectilinear polariser filter significantly helps decrease the problems of reflection on the substrate.

The document^{[3]} likewise presents a method (not illustrated) for creating inward-curved patterns of resin due to use of a “shadow mask”. The shadow mask is a mask comprising opaque parts and transparent parts. The particular character of the transparent parts of the shadow mask is that they are covered with curved patterns made of polymer. It is these mounds, placed on the transparent parts of the mask, which provide inward-curved patterns of resin. The document^{[3]} likewise presents the use of a layer of glycerol between the shadow mask and the substrate covered with resin for replacing the layer of air inevitably found between the shadow mask and the layer of resin. The layer of glycerol therefore acts as a layer of index adaptation between the mask and the layer of resin.

The method described in this document^{[3]} therefore helps to resolve the problem of reflections on the substrate and “Fresnel reflections” which appear for methods of photolithography with inclined light beam. However, it does not contribute any solution to the of angle limitation of the patterns of resin, which can be fabricated.

It is known to be able to produce three-dimensional micro-structures with inclined flanks by using a photolithography technique based on X-rays. For example, the LIGA technique (lithography finished by galvanisation) consists of exposing a photosensitive resin layer, for example a polymer of PMMA type (polylmethyl methacrylate) by means of X-rays originating from a synchrotron. The photosensitive resin layer is then developed. Patterns of resin of good definition are thus formed. To obtain patterns of resin with inclined flanks, by means of a photolithography method via X-rays, a method derived from the LIGA method and described in the documents^{[4]} and ^{[5]} cited at the end of the present description can be utilised. This method described in FIG. 5 consists of several exposures of a substrate 100 covered by a photosensitive resin layer 101 and a mask 501, while preserving the mask 501—substrate 100 ensemble inclined relative to an incident beam of X-rays 500 originating from a synchrotron (not shown). Contrary to ultra-violet rays, X-rays are refracted only slightly when they penetrate the photosensitive resin layer 501. X-rays therefore provide the patterns of resin having an angle of inclination relative to a normal to a principal plane of the substrate superior to that obtained by conventional techniques utilising ultra-violet rays. But photolithography by X-rays all the same comprises major disadvantages.

A first disadvantage associated with the use of this technique stems from the fact that the sources of X-rays (synchrotrons) utilised for executing photolithography by X-rays are very costly and very bulky. The masks utilised in photolithography by X-rays are likewise very costly. Finally, due to its cost and its difficulty of execution photolithography by X-rays is not currently utilised on an industrial scale in methods for the fabrication of integrated circuits.

### DESCRIPTION OF THE INVENTION

The object of the present invention is to propose a fabrication method of patterns by photolithography, as well as a device for carrying out this method. The method and the device are simple to execute and are low cost, as compared to photolithography techniques by X-rays. The present invention produces patterns by photolithography having inclined flanks making an angle far superior to that which can be obtained with the prior art. The present invention likewise concerns a device and a method which overcome problems of parasite reflections which are associated with certain classic photolithography methods with inclined light beam.

To attain these aims, the present invention concerns a fabrication method of one or more patterns by photolithography comprising the following steps:

a) deposit on a substrate of a photosensitive resin layer,

said method comprising the following steps:

b) insulation of the photosensitive resin layer through a mask by a light beam having a main direction, the light beam having previously passed through an optical system, which deflects the main direction of the light beam from a predetermined angle of deviation, such that the main direction presents a non-zero angle of incidence on the mask with a normal relative to the principal plane of the substrate when the light beam penetrates the mask,

c) withdrawal of the mask,

d) development of the photosensitive resin layer so as to obtain patterns with inclined flanks relative to a normal to the principal plane of the substrate as a function of the predetermined angle of deviation.

The present invention likewise concerns a method for producing one or more patterns by photolithography comprising the following steps:
a) deposit on a substrate of a photosensitive resin layer,
   said method comprising the following steps:
b) insulation of the photosensitive resin layer through a mask joined to said photosensitive resin layer or to a layer of index adaptation joined to said layer of resin, by a light beam having a main direction, the light beam having previously passed through an optical system joined to said mask or to a layer of index adaptation joined to said mask, the optical system deflects the main direction of the light beam from a predetermined angle of deviation such that the main direction presents a non-zero angle of incidence on the mask with a normal relative to the principal plane of the substrate when the light beam penetrates the mask,
c) withdrawal of the mask,
d) development of the photosensitive resin layer so as to obtain patterns with inclined flanks relative to a normal relative to the principal plane of the substrate as a function of the predetermined angle of deviation.

According to a particularly advantageous characteristic of the method, the step of depositing of the photosensitive resin layer can be preceded by a step of depositing of at least one absorbent layer of light beams. Therefore, by depositing an absorbent layer of light beams just before the photosensitive resin layer, the reflections of the light beam on the substrate can be limited and parasite insulation of the photosensitive resin layer can thus be avoided.

According to a particularly useful characteristic of the method, following the step a) of deposit of the photosensitive resin layer, a layer of index adaptation can be deposited onto the photosensitive resin layer.

In this way, a layer of index adaptation generally in the form of selected liquid or gel can be deposited between the photosensitive resin layer and the mask for example made of silica, as a function of the step index between the mask and the photosensitive resin layer. The layer of index adaptation has a refraction index greater than that of air and preferably between the refraction index of the mask and the refraction index of the photosensitive resin layer. This adaptation layer thus serves to eliminate Fresnel reflections between the mask and the layer of resin, and at step d) to obtain angles of inclination of the flanks of the patterns of resin greater than those obtained in the prior art.

According to a particularly interesting characteristic of the method, prior to the insulating step of the photosensitive resin layer, a layer of index adaptation is placed between the optical system and the mask.

In this way, just as a layer of index adaptation is deposited between the photosensitive resin layer and the mask, before the insulating step, a layer of index adaptation can be placed in between the mask and the optical system. This second layer of index adaptation is for example in the form of a gel or a liquid deposited on the mask and which diffuses by capillary action between the optical system and the joined mask.

This adaptation layer thus eliminates Fresnel reflections between the optical system and the mask, and at the step d) provides angles of inclination of the flanks of the patterns of resin greater than those obtained in the prior art.

According to particularly advantageous characteristic of the method according to the present invention, the optical system can comprise a prism, a diffraction network, a network of micro-prisms or an optical diffuser.

In this way, a prism, a diffraction network, a network of micro-prisms or an optical diffuser are optical systems, which are capable during the insulation phase of deflecting the main direction of the light beam from a predetermined angle of deviation such that it makes a non-zero angle of incidence on the mask with a normal relative to the principal plane of the substrate when it penetrates the mask.

According to a particularly advantageous characteristic of the method, during the insulating step, the angle of incidence on the mask can vary.

In this way, for example by having the inclination of the optical system vary relative to the main direction of the light beam, the angle of incidence on the mask made by the main direction of the light beam with a normal relative to the principal plane of the substrate can be made to vary. In this manner the resulting insulation angle of the photosensitive resin layer can be varied and after development, patterns of resin with flanks having a variable angle of inclination can be obtained.

According to a particularly useful characteristic of the method, during the step b) of insulation, on one hand the optical system and on the other hand the substrate can be animated relative to one another by a relative movement, the mask being associated either with the optical system, or with the substrate.

In this way, the optical system, for example a prism, can remain fixed while an ensemble formed by the substrate, the photosensitive resin layer and the mask turns on itself. This can produce patterns of resin with inclined flanks in different directions. The optical system, for example a diffraction network, can turn on itself, while an ensemble formed by the mask, the substrate, the photosensitive resin layer remains fixed.

Finally, the mask associated with the optical system can likewise turn on itself, whereas the substrate covered by the photosensitive resin layer remains fixed. By having the optical system and/or the mask turn relative to the substrate, patterns of resin with not necessarily plane flanks and inclined in different directions can be produced.

According to a particularly interesting characteristic of the method, during step b) of insulation, an ensemble formed by the optical system, the mask, and the substrate can be animated by a movement relative to the light beam.

In this way, an ensemble formed by the optical system, for example a prism, by the substrate and the photosensitive resin layer can be fixed, while the main direction of the light beam varies. This can produce patterns of resin of variable inclination.

The invention likewise concerns a device for producing one or more inclined patterns by photolithography, comprising a plate on which rests a substrate, on which rest a photosensitive resin layer, a mask, means for insulating the photosensitive resin layer by means of a light beam having a main direction, the light beam passing through an optical system deflecting by a predetermined angle of deviation the main direction of the light beam such that the main direction of the beam makes a non-zero angle of incidence on the mask with a normal relative to the principal plane of the substrate at the moment when the light beam penetrates the mask.

The invention in addition concerns a device for making one or more inclined patterns by photolithography comprising a substrate on which rests a photosensitive resin layer, the device also comprising a mask of refraction index joined to said photosensitive resin layer or to a layer of index adaptation resting on said layer of resin, an optical system joined to the mask or to a layer of index adaptation resting on the mask, means for insulating the photosensitive resin layer by means of a light beam having a certain main direction, the optical system being capable of deflecting by a predetermined angle of deviation the main direction of the beam, such that the main direction of the light beam makes a non-zero angle of incidence on the mask with a normal relative to the principal plane of the substrate at the moment when the light beam penetrates the mask.

The mask of the device comprises one or more openings. According to a particularly interesting characteristic of the device, the optical system and the openings of the mask can have close indices of refraction.

According to a particularly interesting characteristic of the device, the optical system and the openings of the mask can be made from the same material.

In this way, there is an attempt to limit the jump in refraction index between the optical system and the mask and therefore to limit the deviation of the light beam when the light beam exits from the optical system and penetrates the mask.

According to a particularly advantageous characteristic of the device, the mask is integrated into the photosensitive resin layer.

In this way, the mask can be constituted by an etched metallic layer integrated into in the photosensitive resin layer, such that there is no refraction when the light beam passes from the mask to the photosensitive resin layer. In addition, the Fresnel reflections between the mask and the layer of resin are thus eliminated.

According to a particularly useful characteristic of the device, the optical system can comprise a prism, a diffraction network, a network of micro-prisms or an optical diffuser. In this way, the prism, the diffraction network, the optical diffuser, the network of micro-prisms effectively insulate a photosensitive resin layer to be photo-structured placed on a substrate by means of a light beam inclined relative to a normal relative to the principal plane of the substrate, even when the light beam passes through the prism, the diffraction network, the network of micro-prisms or the optical diffuser according to normal incidence.

According to a particularly interesting characteristic of the device, the device can comprise a layer of index adaptation between the photosensitive resin layer and the mask.

A layer of index adaptation between the photosensitive resin layer and the mask effectively replaces a fine layer of air found inevitably at the interface between the photosensitive resin layer and the mask and thus limits Fresnel reflections of the light beam at the interface between the photosensitive resin layer and the mask.

According to a particularly advantageous characteristic of the device, the device comprises a layer of index adaptation between the mask and the optical system.

A layer of index adaptation between the mask and the optical system replaces a fine layer of air found inevitably at the interface between the mask and the optical system and thus limits Fresnel reflections of the light beam at the interface between the mask and the optical system.

According to a particularly interesting characteristic of the device the adaptation layer situated between the photosensitive resin layer and the mask or/and the adaptation layer situated between the optical system and the mask can be a liquid such as water or a fat fluid.

According to a particularly useful characteristic of the device, the device comprises an absorbent layer of light beams between the substrate and the photosensitive resin layer.

In this way, an absorbent layer of ultra violet rays situated just below the photosensitive resin layer to be photo-structured limits the parasite reflections on a layer situated below the photosensitive resin layer during the exposure step. These parasite reflections appear when the light beam incident to the resin is inclined relative to a normal relative to the principal plane of the substrate. The parasite reflections thus create parasite exposure zones in the photosensitive resin layer and can create parasite patterns of resin after development of the photosensitive resin layer.

According to a particularly useful characteristic of the device, the optical system is mobile relative to the substrate, the mask being associated either to the optical system, or to the substrate.

In this way a plate on which the substrate is located can be in motion, and therefore for example can allow to turn on itself an ensemble formed by the substrate, the photosensitive resin layer and the mask, whereas the optical system remains fixed.

According to a particularly useful characteristic of the device according to the present invention, it can comprise a plate on which rests the substrate, mobile in rotation relative to the light beam.

According to a particularly beneficial characteristic of the device according to the present invention it can comprise a plate on which rests the substrate, inclinable relative to the light beam.

It is understood that the movements of the plate can be combined and the inclination of the plate can be varied, while it is mobile in rotation.

### BRIEF DESCRIPTION OF THE FIGURES

The present invention will be better understood from the description of given exemplary embodiments, purely by way of indication and in no way limiting, with reference to the attached diagrams in which:

FIGS. 1A-1C, already described, illustrate examples of a photolithography method according to the known art;

FIGS. 2A-2B, 3A-3C, 4, 5 already described, illustrate an example of a photolithography method which enables patterns of resin to be made by photolithography with inclined flanks according to the known art;

FIGS. 6A-6C, 7, 8, 9, 10A, 10B, 11A, 11B, 12, illustrate examples of a photolithography method for creating one or more patterns of resin with inclined flanks according to the present invention;

FIGS. 13A-13E illustrate examples of devices for creating one or more patterns with inclined flanks by photolithography according to the present invention.

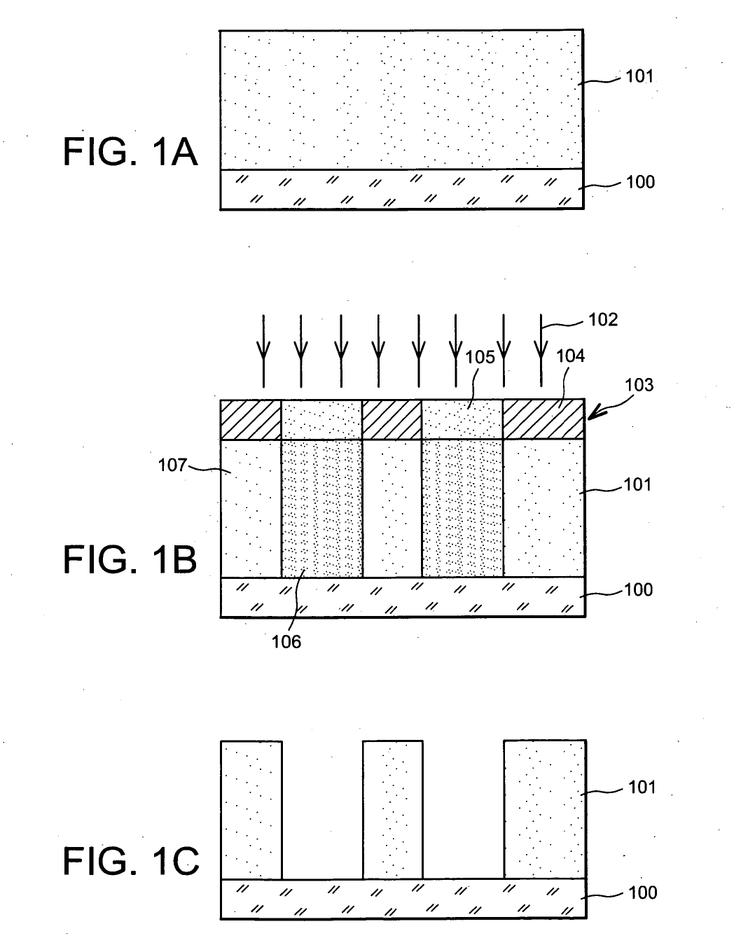

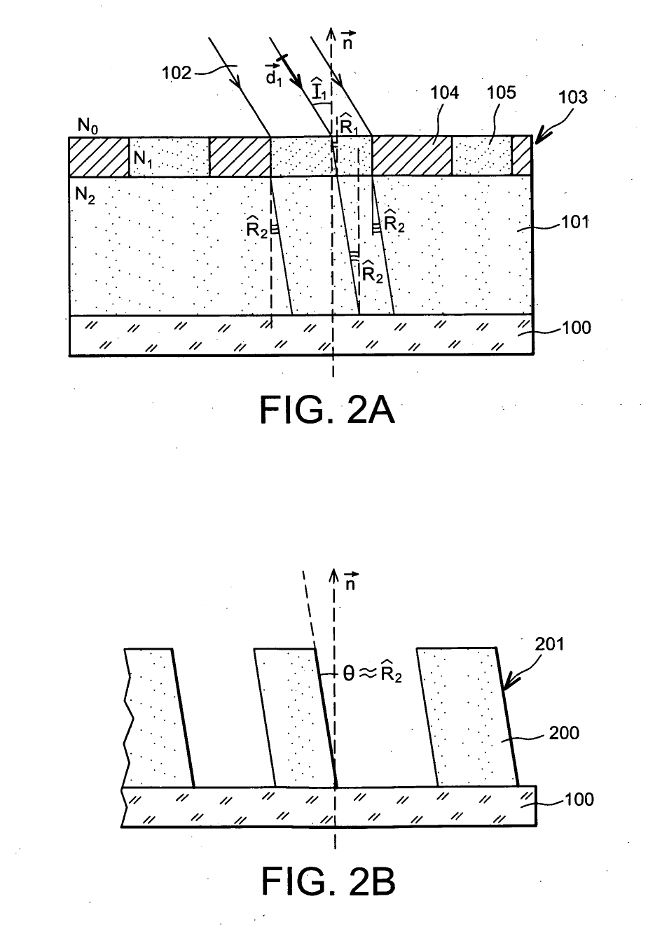

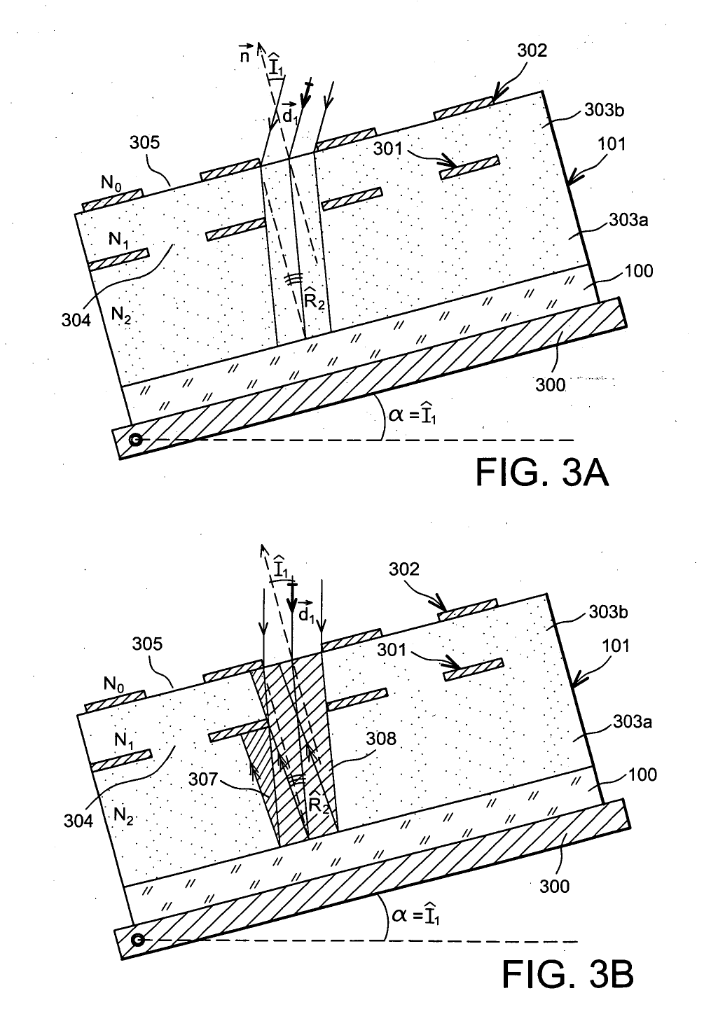

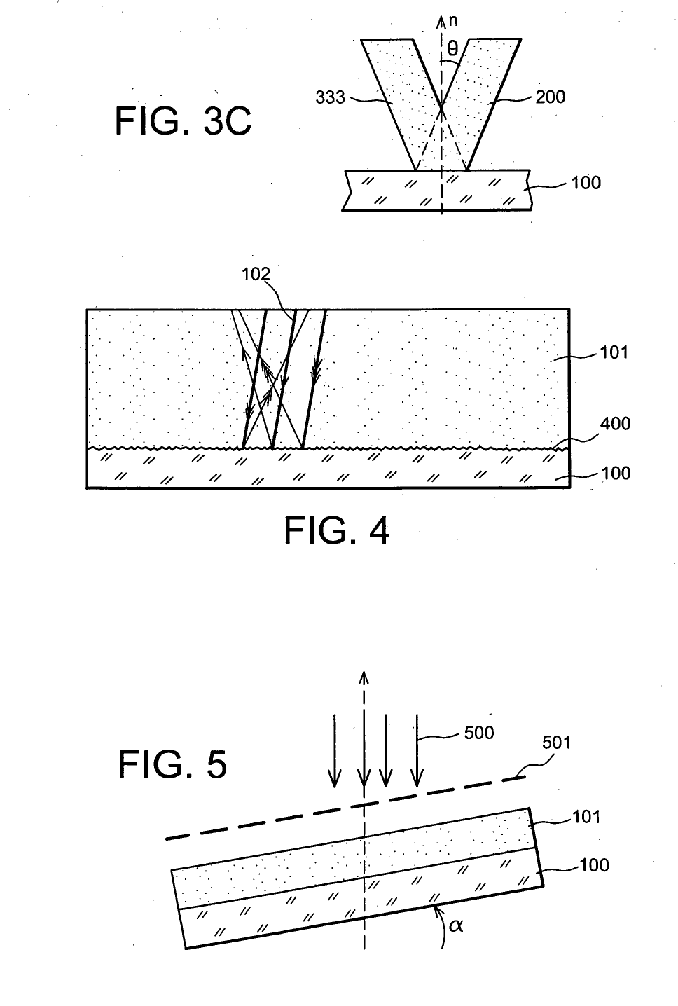

Identical, similar or equivalent parts of the different figures carry the same reference numerals so as to facilitate passage from one figure to the next.

The different parts illustrated in the figures are not necessarily different according to a uniform scale for making the figures more legible.

### DETAILED DESCRIPTION OF PARTICULAR EMBODIMENTS

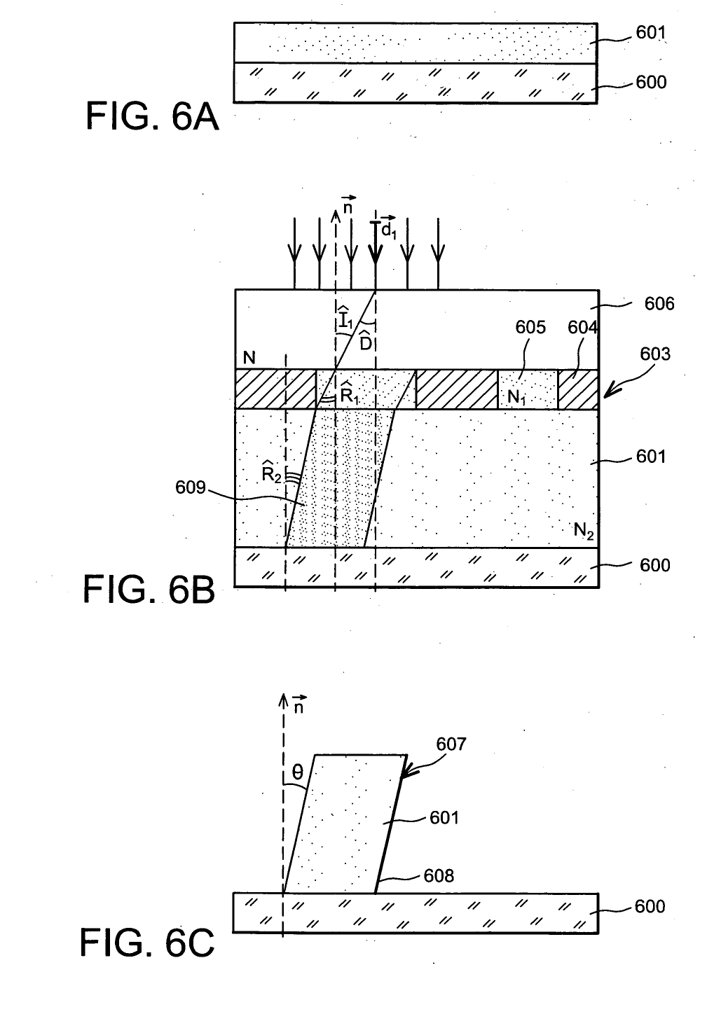

A first example of a fabrication method of one or more patterns by photolithography, with inclined flanks, according to the present invention, is illustrated by FIGS. 6A-6C.

The first step of this method illustrated by FIG. 6A consists of depositing a photosensitive resin layer 601 on a substrate 600. The photosensitive resin layer 601, for example a negative photosensitive resin layer based on epoxy such as that marketed by the company Micro-Chemical Corporation under the reference “SU-8” is deposited using a conventional method and has a thickness for example of around 100 μm. The substrate 600 is for example made of glass, silicon, etc.

Next, in the course of a step illustrated by FIG. 6B, a mask 603 is attached to the photosensitive resin layer 601, then an optical system 606 of refraction index N is attached above the mask 603. The mask 603 comprises zones 604 opaque to light, for example made of metal such as chrome, and zones 605 transparent to light for example made of silica. The photosensitive resin layer 601 of refraction index N₂ is then insulated through the mask 603 of refraction index N₁. The insulation is completed by a light beam 602 originating for example from a source with ultra-violet rays (not shown in the figure) emitting for example about the wavelength of 365 nm. The light beam 602 has a main direction \vec{d}₁ and penetrates, in normal incidence, the optical system 606 of refraction index N, joined to the mask•603. The optical system 606 deflects the main direction \vec{d}₁ of the optical beam 603 by an angle of deviation \hat{D}. The angle of deviation \hat{D} is predetermined according to the geometric or/and physical characteristics of the optical system 606. On exiting the optical system 606, the main direction of the beam makes an angle of incidence Î₁ on the mask 603 with a normal n relative to the principal plane of the substrate 600. Next, the light beam 602 passes through the mask 603 and its main direction \vec{d}₁ is once again deflected and makes an incident angle \hat{R}₁ on the layer of resin 601 with the normal \vec{n} relative to the principal plane of the substrate 600. Next, the beam 602 penetrates the photosensitive resin layer 601 and the main direction \vec{d}₁ of the light beam 602 is once more deflected and makes a resulting insulation angle \vec{R}₂ with the normal \vec{n} relative to the principal plane of the substrate 600. The photosensitive resin layer 601 therefore comprises insulated zones 609 inclined relative to the normal to the principal plane of the substrate 600.

Introducing the optical system 606 capable of deflecting the main direction \vec{d}₁ of the light beam 602 helps reduce the difference between the angle of incidence Î₁ on the mask 603 and the resulting insulation angle \hat{R}₂. The optical system 606 therefore insulates the photosensitive resin layer 601 according to a resulting insulation angle \vec{R}₂ more important than with the methods according to the prior art.

The optical system 606 can be advantageously made from a material whereof the refraction index is close to that of the mask 603, so that the optical system 606 has a refraction index N close to the index N₁ of the mask 603. In this case the incident angle \vec{R}₁ on the layer of resin 601 is quasi equal to the angle of incidence Î₁ on the mask 603; the main direction \vec{d}₁ of the light beam 602 is unchanged when the beam 602 passes through the optical system 606 when the beam 602 passes through the mask 603. By using an optical system 606 and a mask 603 made from the same material, the difference between the angle of incidence Î₁ and the resulting insulation angle \hat{R}₂ can therefore be reduced further still and allow insulation of the photosensitive resin layer with an even more significant resulting insulation angle \hat{R}₂.

After the insulating step, the mask 603 and the optical system 606 are removed from the photosensitive resin layer 601. Next, the photosensitive resin layer 601 is developed so as to produce patterns 607 of resin which have inclined flanks 608. The inclined flanks 608 of the patterns 607 describe an angle θ with a normal \hat{n} relative to the principal plane of the substrate 600 (FIG. 6C). The angle δ is quasi equal to the resulting insulation angle \hat{R}₂. The method according to the present invention therefore produces patterns 607 of resin with an angle θ of the flanks 608 of patterns 607, a function of the predetermined angle of deviation \hat{D} of the optical system 606. In addition, the angle θ of the flanks 608 of patterns 607 can be much greater than that obtained with methods according to the prior art.

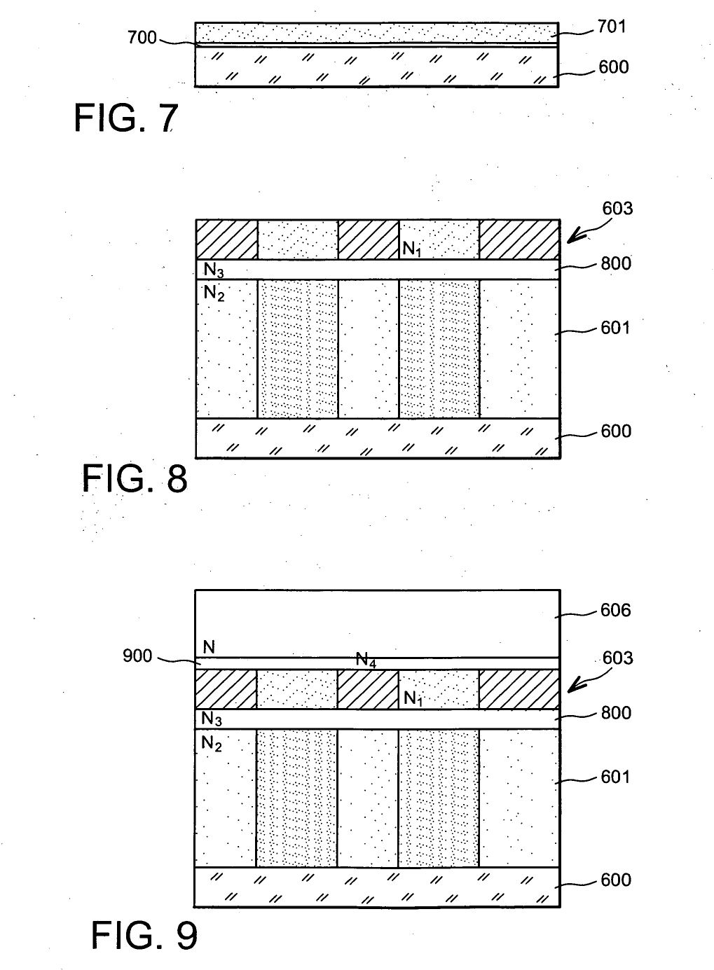

One embodiment of the method according to the present invention consists of depositing, before the step of depositing of the photosensitive resin layer 601 illustrated by FIG. 6A, an absorbent layer of light beams 700 on the substrate 600. The deposit of the absorbent layer 700 of light beams can be followed by the deposit of a protective layer 701 which allows the absorbent layer 700 of light beams not to be dissolved by the solvents of the resin 601 of the substrate 600 when the substrate 600 is subjected to significant constraints (FIG. 7). The absorbent layer of light beams 700 effectively prevents the reflection on the substrate 600 of ultra-violet rays, in the case of photolithography by ultra-violet rays. The absorbent layer of light beams 700 can for example be a thin organic layer of BARC type (Bottom Anti Reflective Coating denoting an anti-reflective base layer). Its thickness can be for example of the order of 80 nm. As one embodiment this absorbent layer of light beams 700 can be a resin or a polymer mixed with a carbon powder or can be an inorganic layer such as a layer comprising at least a SiO₂/TiO₂ pile. The layer 701 can comprise for example a polymer of the elastomer family.

Another embodiment of the method according to the present invention consists of depositing, before the insulation phase illustrated by FIG. 6B, a layer of index adaptation 800 on the photosensitive resin layer 601. This layer of index adaptation 800 has a refraction index N₃ and is placed between the photosensitive resin layer 601 and the mask 603 placed above it. The refraction index N₃ is close to the index N₁ of the mask 603 and the index N₂ of the photosensitive resin layer 601 between which the layer of index adaptation 800 is placed so as to minimise the Fresnel reflection at the interface mask 603-photosensitive resin layer 601. The Fresnel reflections are actually due to a fine layer of air found inevitably between the mask 603 and the photosensitive resin layer 601. The layer of index adaptation 800 thus helps replace the fine layer of air of refraction index equal to 1 by a more refractive material. Therefore the step index caused by the fine layer of air is limited by replacing it by the layer of index adaptation 800 of refraction index N₃ greater than 1 and between N₁ and N₂. The layer of index adaptation 800 can take the form of a gel or a liquid such as water. It can be deposited on the photosensitive resin layer by means of a micro-pipette for example.

Water has a refraction index approximately equal to 1.33 of between N₁ and N₂ and diffuses by capillary action between the photosensitive resin layer 601 and the mask 603 placed above it to form the layer of index adaptation 800 (FIG. 8). The layer of index adaptation 800 can be likewise formed with a base of glycerine of refraction index approximately equal to 1.47 of between N₁ and N₂ or by a rich liquid.

Another embodiment of the method according to the present invention consists of depositing another layer of index adaptation 900 on the mask 603 after the layer of index adaptation 800 and the mask 603 have been deposited and before the insulating step illustrated by FIG. 6B. The other layer of index adaptation 900 is interposed in between the mask 603 and the optical system 606 which is then attached above. A fine layer of air is located inevitably between the mask 603 and the optical system 606. The other layer of index adaptation 900 has a refraction index N₄ ideally between the index N of the optical system 606 and the index N₂ of the layer of resin 601. It helps to replace the fine layer of air of refraction index close to 1 by a more refractive material. The other layer of index adaptation 900 therefore prevents Fresnel reflections between the mask 603 and the optical system 606 by decreasing the step index jump between the optical system 606 and the mask 603.

The other layer of index adaptation 900 can be constituted for example by a liquid such as water, or advantageously by a gel based on glycerine or a fat fluid deposited on the mask 603. The advantage of glycerine is also to allow the optical system 606 to shift relative to the mask 603, while ensuring the index adaptation between these two elements.

The fluid or the liquid deposited on the mask 603 is compressed by the optical system 606 placed above it. The fluid diffuses by capillary action between the mask 603 and the optical system 606 to form the other layer of index adaptation (FIG. 9).

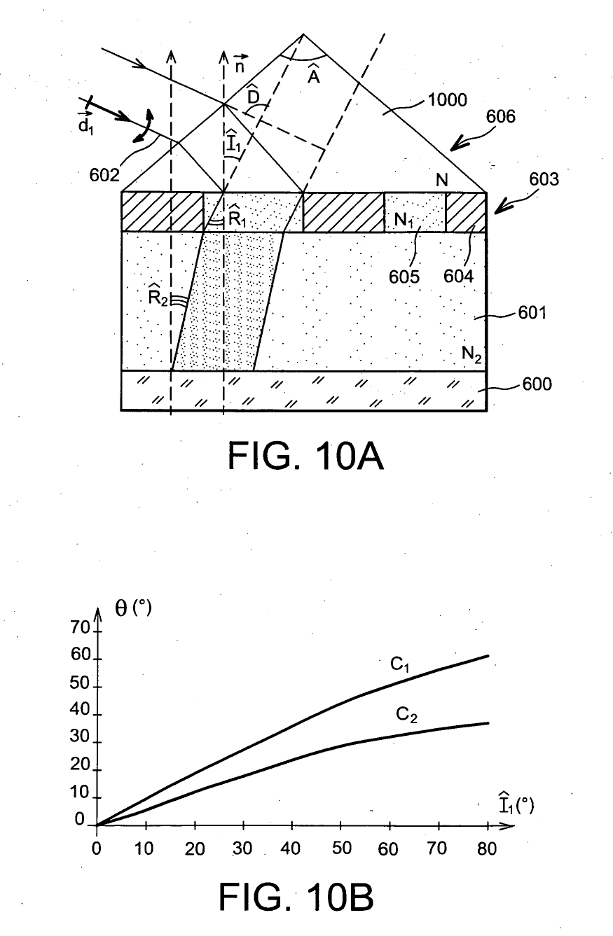

According to one embodiment of the method illustrated by FIG. 10A, the optical system 606 utilised during the insulation phase illustrated by FIG. 6B can be formed by a prism 1000. The prism 1000 has a refraction index N, and is sized at an angle Â to the apex, which allows it to deflect the light beam 602 by a predetermined angle of deviation \hat{D}, as a function of the refraction index of air N₀, its refraction index N, and its angle to the apex angle Â.

The light beam 602 has a main direction \hat{d}₁ and penetrates the prism 1000 joined to the mask 603 at any incidence. The prism 1000 then deflects the main direction \hat{d}₁ of the light beam 602 by the angle of deviation \hat{D}. On exiting the prism 1000, the main direction \hat{d}₁ of the beam 602 makes an angle of incidence Î₁ on the mask 603 with a normal \hat{n} relative to the principal plane of the substrate 600. Next, the light beam 602 passes through the mask 603 and its main direction \hat{d}₁ is once again deflected and thus makes an incident angle R₁ on the layer of resin 601 with a normal \hat{n} relative to the principal plane of the substrate 600. Next, the light beam 603 penetrates the photosensitive resin layer 601 and the main direction \hat{d}₁ of the light beam 602 is once again deflected. The main direction \hat{d}₁ thus makes a resulting insulation angle R₂ with the normal \hat{n} relative to the principal plane of the substrate 600.

The prism 1000 can be formed from a mineral material or else for example a polymer. In addition, the prism 1000 can be advantageously formed by a material of refraction index close to that of the mask 603 therefore having a refraction index N close to N₁. The prism 1000 deflects the main direction \hat{d}₁ of the light beam irrespective of the incidence of the light beam 602 which passes through it. This implies that with such a method there is no need to incline the substrate 600 to insulate the photosensitive resin layer 601 with an inclined light beam.

According to one variant of the example of the method illustrated by FIG. 10A, the direction \vec{d}₁ of the light beam varies during the course of the insulating step, which causes a variation in the angle of incidence Î₁ on the mask 603. In this way, the resulting insulation angle \hat{R}₂ of the photosensitive resin layer 601 can be varied during the insulating step. Having the resulting insulation angle \hat{R}₂ of the photosensitive resin layer 601 varied enables the creation of patterns of resin by photolithography, which have no inclined and non-flat flanks.

FIG. 10B is a graph which illustrates the evolution curve C₁, drawn in full lines, of an angle θ of flanks 608 of patterns 607 obtained using a method using the device illustrated by FIG. 10A. The optical system utilised here is a prism 1000 of refraction index N equal to 1.46, as a function of the variation of the angle of incidence Î₁ on the mask 603. The photosensitive resin layer utilised has a refraction index N₂ equal to 1.67. FIG. 10B illustrates likewise the evolution curve C₂, drawn in dotted lines of the angle θ of the flanks 608 of the patterns 607 as a function of the variation of the angle of incidence Î₁ on the mask 603 obtained according to a method similar to the method of the prior art illustrated by FIGS. 6B-6C, but without using an optical system.

For angles of incidence Î₁ on the mask 603 varying from 0° to 50°, C₁ and C₂ are growing and substantially linear. The curve C₁ has a growth rate greater than the curve C₂. For an angle of incidence Î₁ on the mask approximately equal to 50°, the value of the angle δ of the flanks 608 of the patterns 607 is for example approximately 28° on C₂ and approximately 42° on C₁. Next, for an angle of incidence Î₁ varying from 50° to 80°, the curves C₁ and C₂ grow to reach a threshold limit to Î₁ approximately equal to 80°. When the angle of incidence Î₁ is equal to 80°, the value of the angle θ of the flanks 608 of the patterns 607 is around 38° on the curve C₂ and around 60° on the curve C₁. FIG. 10B thus shows that the method illustrated by FIG. 10A using a prism 1000 as optical system provides patterns by lithography which have flanks having an angle θ of the flanks 608 of the patterns 607 far greater than that which can be obtained with the methods without an optical system, and which does not exceed 38°.

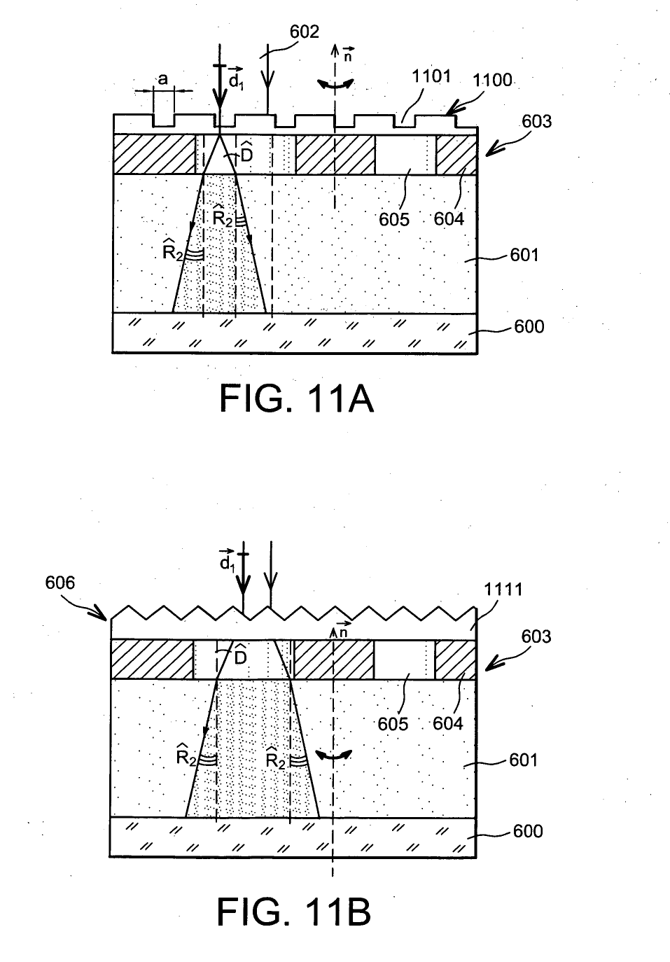

According to one variant illustrated by FIG. 11A of the example of the insulation phase of the method illustrated by FIG. 6B, the optical system 606 utilised can be formed by a diffraction network 1100 in the form of a plaque, for example made of glass in which parallel etched structures 1101 of width a, are ordered uniformly, a being of the order of 0.3 μm for example for a light beam emitting about the wavelength 365 nm.

The diffraction network 1100 deflects the main direction \vec{d}₁ of the light beam 602 by an angle of deviation \hat{D} as a function of the wavelength of the light beam 602 and of a. The diffraction network 1100 insulates the photosensitive resin layer with a resulting insulation angle \hat{R}₂ and an angle −\hat{R}₂, functions of the angle of deviation \hat{D}.

In addition, the variant illustrated by FIG. 11A differs from the method of FIG. 6B in that the diffraction network 1100 associated with the mask 603 turns on itself during the insulating step, while the photosensitive resin layer 601 and the substrate 600 remain immobile.

According to one embodiment illustrated by FIG. 11B of the example of insulating step of the method illustrated by FIG. 6B, the optical system utilised can comprise a network of micro-prisms 1111. A network of micro-prisms can be in the form of a plaque transparent to light beam covered with micro-prisms distributed uniformly on the plaque. The network of micro-prisms 1111 can be made of a material for example based on glass, silica or polymer. The network of micro-prisms 1111 has a function similar to the diffraction network 1100 illustrated by FIG. 11A.

In effect, the network of micro-prisms 1111 deflects the main direction \vec{d}₁ of the light beam 602 by an angle of deviation \hat{D}. The network of micro-prisms 1111 therefore insulates the photosensitive resin layer with a resulting insulation angle \hat{R}₂ as a function of the angle of deviation \hat{D}.

In addition, the embodiment illustrated by FIG. 11B differs from the method of FIG. 6B in that the mask 603 associated with the photosensitive resin layer 601 and the substrate 600 turns on itself, whereas the network of micro-prisms 1111 remains immobile during the insulating step.

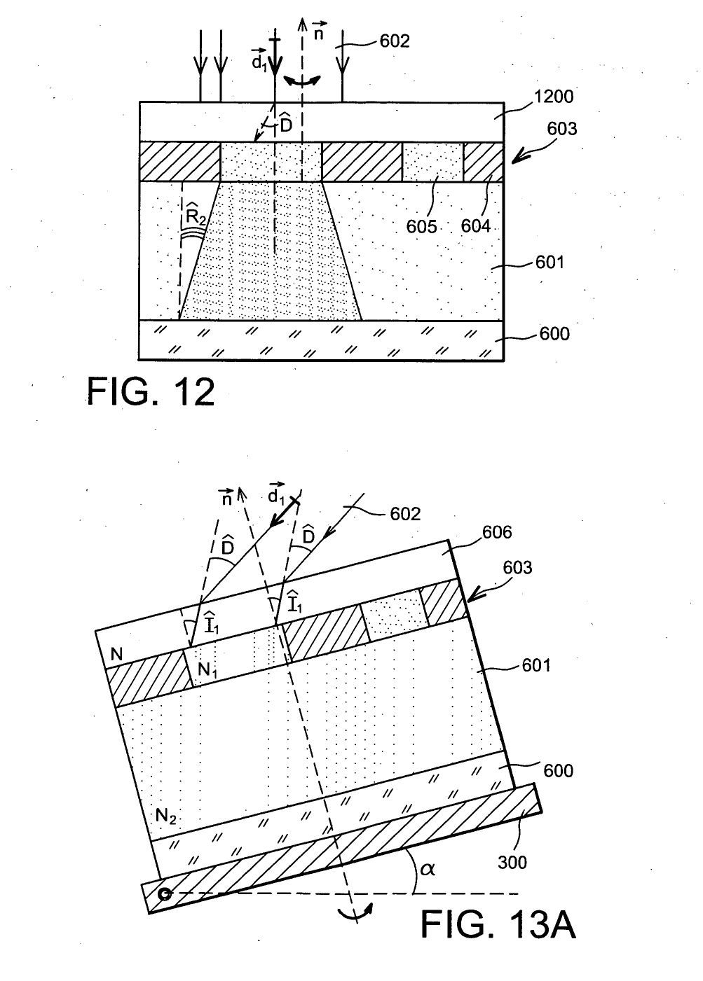

According to one embodiment illustrated by FIG. 12 of the example of the insulation phase of the method illustrated by FIG. 6B, the optical system 606 utilised can be formed by an optical diffuser 1200 of index N, which deflects the light beam 602 by a predetermined angle of deviation \hat{D} as a function of N. The advantage of the optical diffuser 1200 is to be flat and therefore be easily integrated in a photolithography device, which insulates the photosensitive resin layer with a resulting insulation angle \hat{R}₂ as a function of the angle of deviation \hat{D}. The optical diffuser 1200 can be for example a simple pane of glass.

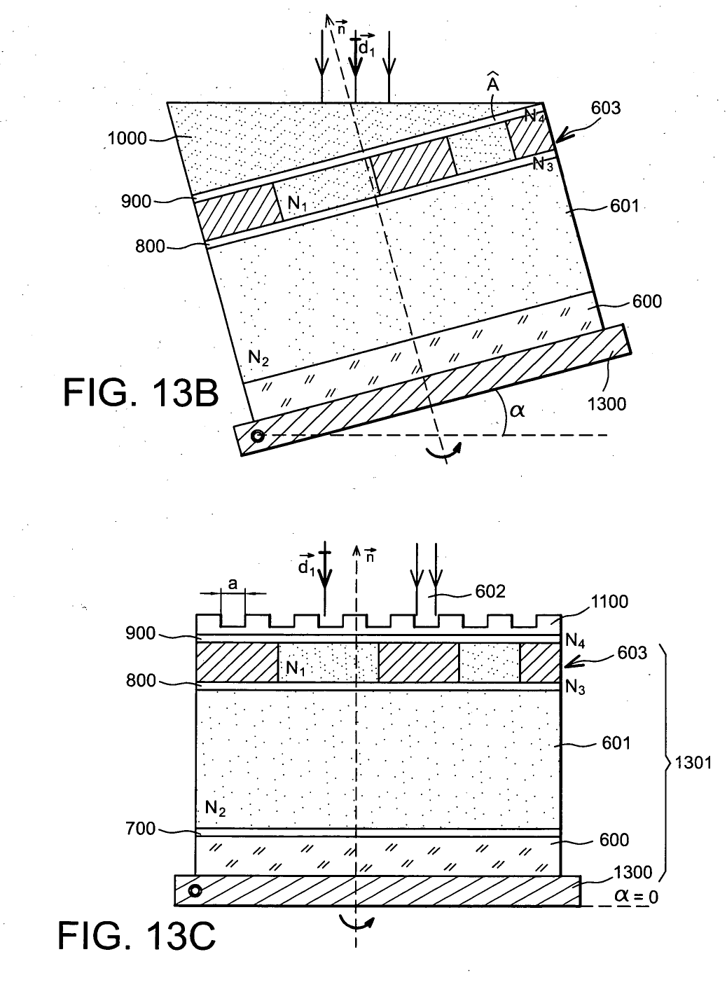

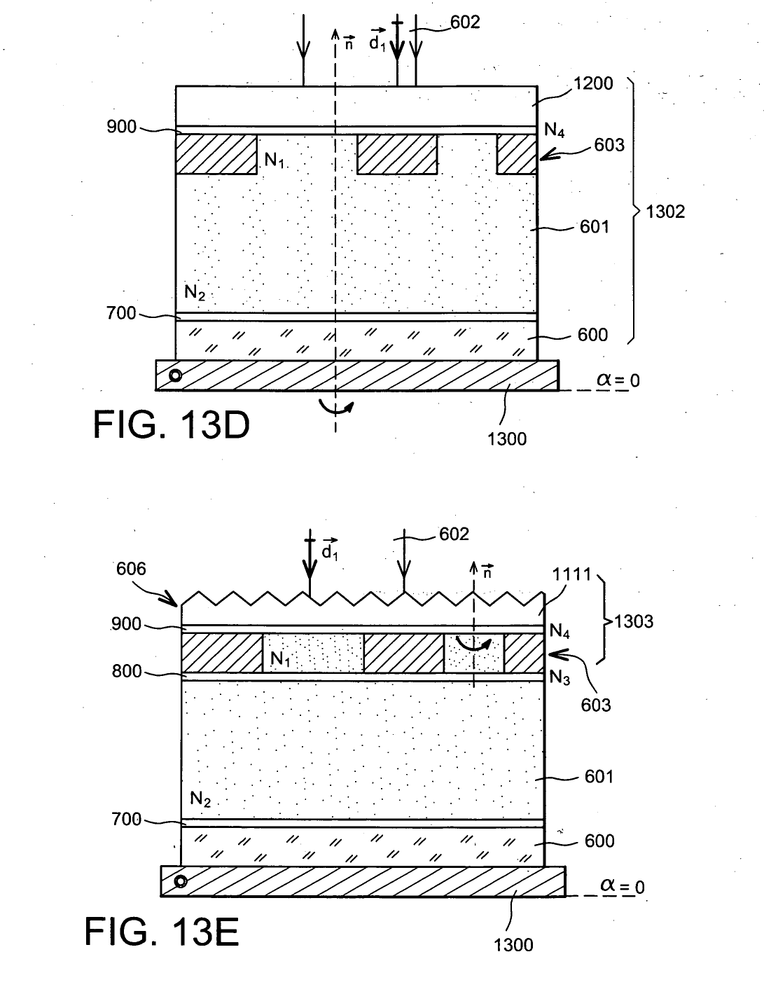

FIG. 13A illustrates an example of a device for creating patterns with inclined flanks by photolithography. The device comprises a substrate 600 on which rests a photosensitive resin layer 601 of refraction index N₂, a mask 603 of refraction index N₁ joined to the photosensitive resin layer 601, an optical system 606 of refraction index N joined to the mask 603. The device likewise comprises a light beam 602 of main direction \vec{d}₁ which serves to insulate the photosensitive resin layer 601 through the mask 603. The device likewise comprises a plate 1300 for adopting a variable angle of inclination α and optionally turning on itself on which rests the substrate 600. The optical system 606 is capable of deflecting the main direction \vec{d}₁, irrespective of the direction \vec{d}₁ of the light beam 602 which passes through it, by a predetermined angle of deviation \hat{D}, such that the main direction \vec{d}₁ can be inclined relative to a normal \vec{n} relative to the principal plane of the substrate 600 at the moment of penetrating through the photosensitive resin layer 601. The light beam 602 is from a source of light beams (not shown in FIG. 13A) for example a source of ultra-violet rays. The optical system 606 is made of a material transparent to the wavelength of the source. The optical system 606 is for example made from a material based on silica or based on polymer. The mask 603 can likewise be formed by a material based on silica or based on polymer.

FIG. 13B illustrates another example of a device according to the present invention and which differs from that of FIG. 13A in that the optical system is a prism 1000 sized at an angle Â. The prism 1000 is fixed relative to an ensemble 1301 constituted by the mask 603, the photosensitive resin layer 601, the substrate 600 and the plate 1300. The plate 1300 is capable of adopting an angle of inclination α substantially equal to Â and turning on itself, so as to make the ensemble 1201 turn on itself. Inclining the plate 1300 by an angle α substantially equal to the angle Â produces a light beam 602 normal to the prism 1000 and insulates the photosensitive resin layer 601 with the maximum luminous intensity. The prism 1000 is formed from the same material as the mask 603, for example a material based on polymer, and is joined to the mask 603. The prism has a refraction index N equal to the refraction index N₁ of the mask. In addition, the prism 1000 is sized at an angle Â which deflects the light beam 602 by a predetermined angle of deviation \hat{D} as a function of the index of the air N₀, the refraction index of the prism N, and the angle Â. On the other hand the device of FIG. 13B likewise differs from that of FIG. 13A in that it comprises a first layer of index adaptation 800 situated between the photosensitive resin layer 601 and the mask 603 and which has a refraction index N₃. The first layer of index adaptation 800 is for example water or a rich liquid such as glycerine, whereof the refraction index N₃ is close to that N₁ of the mask and to that N₂ of the photosensitive resin layer 601.

This first layer of index adaptation 800 minimises Fresnel reflections between the mask 603 and the photosensitive resin layer 601. The device of FIG. 13B differs likewise from that of FIG. 13A in that it also comprises a second layer of index adaptation 900 having a refraction index N₄. The second layer of index adaptation 900 is for example water or a fat fluid such as glycerine. The second layer of index adaptation 900 is situated between the mask 603 and the optical system 606. The second layer of index adaptation 900 has a refraction index N₄ close to the index N of the optical system 606 and the index N₁ of the mask 603. By minimising the presence of air between the optical system 606 and the mask 603 on the one hand and between the mask 603 and the resin layer 601 on the other hand, the joining of the layers of index adaptation 800 and 900 produces angles of inclination of the flanks of the patterns of resin greater than those obtained in the prior art.

The device of FIG. 13B differs finally from that of FIG. 13A in that it comprises an absorbent layer of light beams 700, situated between the substrate 600 and the photosensitive resin layer 601. The absorbent layer of light beams 700 serves to prevent ultra-violet rays from being reflected on the substrate in the event where the light beam 602 comes from a source of ultra-violet light. The absorbent layer of light beams 700 can be formed from a single layer or a stack of sub-layers. The absorbent layer of light beams 700 can be for example a resin mixed with carbon pigments.

FIG. 13C illustrates another example of a device according to the present invention, which differs from that of FIG. 13B in that the optical system is a diffraction network 1100. In addition, the diffraction network 1100 is mobile relative to a first ensemble 1301 formed by the mask 603, the photosensitive resin layer 601, the substrate 600 and the plate 1300. Finally, the plate 1300 has a zero angle of inclination α. It is capable of turning on itself.

FIG. 13D illustrates another example of a device according to the present invention, which differs from that of FIG. 13A in that the optical system is an optical diffuser 1200. The optical diffuser 1200, the mask 603, the photosensitive resin layer 601, the substrate 600, and the plate 1300 form a second ensemble 1302 able to turn on itself and mobile relative to the light beam 602.

The device likewise differs in that the mask 603, for example a layer of etched chrome, is directly integrated into the photosensitive resin layer 601. In this case the index of the mask N₁ is equal to that of the resin N₂. The device likewise comprises an absorbent layer of light beams 700, situated between the substrate 600 and the photosensitive resin layer 601 and a layer of index adaptation 900 which has a refraction index N₄. Finally, the plate 1300 has an angle of inclination α.

FIG. 13E illustrates another example of a device according to the present invention, which differs from that of FIG. 13A in that the optical system is a network of micro-prisms 1111. The network of micro-prisms 1111 associated with the mask 603, form a third ensemble 1303 capable of turning on itself relative to the photosensitive resin layer 601 to the substrate 600 and the plate 1300. The third ensemble 1303 is likewise mobile relative to the light beam 602. Finally, the plate 1300 has an angle of inclination α equal to zero.

### CITED DOCUMENTS

[1]: “Microfabrication of 3D Multidirectional Inclined Structures by UV Lithography and Electroplating”; C. Beuret, G.-A Racine, J. Gobet, R. Luther, N. F. de Rooij; asulab S. A. Neuchatel Switzerland; 1994 IEEE©.
[2]: “Procede de fabrication de micro elements de connexion de forme conique”; T, IEE Japan vol. 122-E no. 2; 13 09 2002.
[3]: “Application of Shadow Mask and Polarized Inclined-Exposure for Curved SU-8 Structures on Inclined Surface”; Kuo-Yung Hung, Fan-Gang Tseng, from the Department of Engineering and System Science of Tsing Hua University in Taiwan, presented during the HAMST 2003 conference at Montrerey Calif. USA, 15-17 Jun. 2003.
[4]: “Sloped Irradiation Techniques in Deep X-Ray Lithography for 3-D shaping of Micro-structures”; Gregor Feiertag, Wolfgang Ehrfeld, Heinz Lehr, Martin Schmidt; Institute of Microtechnology Mainz GmbH, Carl-Zeiss-Straβe 55219 Mainz, Germany; ©1997 SPIE.
[5]: “Multi-level Micro-structures and Mold Inserts Fabricated with Planar and Oblique X-ray Lithography of SU-8 Negative Photoresist”; Linke Jian, Yohanes M. Desta, Jost Goettert; Louisiana State University Center for Advanced Micro-structures and Devices; ©2001 SPIE.

1. A method for producing one or more patterns by photolithography comprising the following steps:
a) deposit on a substrate of a photosensitive resin layer, said method comprising the following steps:
b) insulation of the photosensitive resin layer through a mask joined to said photosensitive resin layer or to a layer of index adaptation joined to said layer of resin, by a light beam having a main direction, the light beam having previously passed through an optical system joined to said mask or to a layer of index adaptation joined to said mask, which deflects the main direction of the light beam by a predetermined angle of deviation such that the main direction presents a non-zero angle of incidence on the mask with a normal relative to the principal plane of the substrate when the light beam penetrates the mask,
c) withdrawal of the mask,
d) development of the photosensitive resin layer so as to produce patterns with inclined flanks relative to a normal relative to principal plane of the substrate as a function of the predetermined angle of deviation.

2. The method according to claim 1, the step of depositing the photosensitive resin layer being preceded by a step of depositing at least one absorbent layer of light rays.

3. The method according to claim 1, wherein after the step a) of deposit of the photosensitive resin layer, a layer of index adaptation is deposited on the photosensitive resin layer.

4. The method according to claim 1, wherein before the step of insulating the photosensitive resin layer, a layer of index adaptation is placed between the optical system and the mask.

5. The method according to claim 1, wherein the optical system comprises a prism, a diffraction network, an optical diffuser, or a network of micro-prisms.

6. The method according to claim 1, wherein during the insulation step b) the angle of incidence on the mask varies.

7. The method according to claim 1, wherein during the insulation step b) one the one hand the optical system and on the other hand the substrate are animated by a relative movement relative to one another, the mask being associated either with the optical system, or with the substrate.

8. The method according to claim 1, wherein during the insulation step b) an ensemble formed by the optical system, the mask, and the substrate is animated by a relative movement relative to the light beam.

9. A device for producing one or more inclined patterns by photolithography, comprising a substrate on which rests a photosensitive resin layer of refraction index, also comprising: a mask of refraction index joined to said photosensitive resin layer or to a layer of index adaptation resting on said layer of resin, an optical system joined to the mask or to a layer of index adaptation resting on the mask, means for insulating the photosensitive resin layer by means of a light beam of main direction, the optical system being capable of deflecting by a predetermined angle of deviation the main direction of the light beam, such that the main direction makes a non-zero angle of incidence on the mask with a normal relative to the principal plane of the substrate at the moment when the light beam penetrates the mask.

10. The device according to claim 9, wherein the mask comprises one or more openings, the optical system and the openings of the mask having close indices of refraction.

11. The device according to claim 9, wherein the mask comprises one or more openings, the optical system and the openings of the mask being made of the same material.

12. The device according to claim 9, wherein the mask is integrated into the photosensitive resin layer.

13. The device according to claim 9, wherein the optical system comprises a prism, a diffraction network, a network of micro-prisms or an optical diffuser.

14. The device according to claim 9, wherein that it comprises a layer of index adaptation between the photosensitive resin layer and the mask.

15. The device according to claim 9, the device comprises a layer of index adaptation between the optical system and the mask.

16. The device according to claim 14, wherein the adaptation layer situated between the photosensitive resin layer and the mask or/and the adaptation layer situated between the optical system and the mask is a liquid such as water or a fat fluid.

17. The device according to claim 9, comprising an absorbent layer of light beams between the substrate and the photosensitive resin layer.

18. The device according to claim 9, the optical system is mobile relative to the substrate, the mask being associated either with the optical system or the substrate.

19. The device according to claim 9, comprising a plate, on which rests the substrate, mobile in rotation relative to the light beam.

20. The device according to claim 9, comprising a plate on which rests the substrate, inclinable relative to the light beam.
